(19) United States
(12) Patent Application Publication
(10) Pub. No.: US 2013/0156636 A1
(43) Pub. Date: Jun. 20, 2013

(54) SEMI-HEUSLER/HEUSLER ALLOYS HAVING TAILORED PHASE SEPARATION

(71) Applicants: Martin Koehne, Asperg (DE); Tanja Graf, Eltville (DE); Hans Joachim Elmers, Partenheim (DE); Claudia Felser, Dresden (DE)

(72) Inventors: Martin Koehne, Asperg (DE); Tanja Graf, Eltville (DE); Hans Joachim Elmers, Partenheim (DE); Claudia Felser, Dresden (DE)

(21) Appl. No.: 13/703,553

(22) PCT Filed: Apr. 15, 2011
(86) PCT No.: PCT/EP2011/056000

§ 371 Date: Feb. 20, 2013

(30) Foreign Application Priority Data
Jun. 11, 2010 (DE) 102010029968.5

(51) Int. Cl. H01L 35/28

(52) U.S. Cl. CPC H01L 35/28
USPC 420/576

(57) ABSTRACT

An inorganic, intermetallic compound contains at least two elements per formula unit and consists of at least two phases, at least one phase being semiconducting or semimetallic, these at least two phases are immiscible with each other and are thermodynamically stable, so as to allow the thermal conductivity of semi-Heusler alloys to be reduced while at the same time maintaining the electrical conductivity and the thermoelectric voltage.

### FIELD OF THE INVENTION

The present invention relates to an inorganic, intermetallic compound that contains at least two elements per formula unit and consists of at least two phases.

### BACKGROUND INFORMATION

Thermoelectric materials generate an electric voltage when they are exposed to a temperature gradient. This is used in thermoelectric generators to produce electric energy. However, the efficiency in converting a temperature gradient into current is less than 10% in the case of materials that have been used up to now. Therefore, in order to achieve a better efficiency, materials are required which conduct electric current well but conduct heat poorly. Good current conductors which, as a rule, are just as good thermal conductors, are distinguished at an atomic plane by a uniform lattice structure. Electricity spreads in it in the form of electron streams, heat in the form of lattice oscillations. Irregularities in the lattice structure, such as missing atoms, may reduce the thermal conductivity but also impair the electrical conductivity.

However, if single atoms are caught in crystalline cage structures, independently of the crystal lattices, these atoms oscillate and thereby lower the thermal conductivity by disturbing the thermal waves. However, the electrical conductivity is not impaired thereby.

The development of cost-effective, environmentally compatible and resource-saving thermoelectric volume materials opens up, for the first time, the perspective of producing thermoelectric generators for gaining energy from waste heat in mass production. These thermoelectric generators may be used in numerous applications, in order to make the waste heat, that has not been utilized for generating current up to now, usable. Examples for its application are the gaining of current from waste heat in the exhaust gas tract of an automobile or from hot gas waste heat of industrial thermal processes.

One of the volume materials, that come into consideration for thermoelectric generators, is semi-Heusler alloys. This class of materials of the Heusler alloys stands out, among other things, in that certain Heusler alloys of nonmagnetic metals are ferromagnetic.

Up to now, more than 250 semi-Heusler alloys have become known, almost all being semiconductors or semimetals, most of them having relatively small band gaps, which makes them interesting with regard to their good thermoelectric properties. One difficulty with the semi-Heusler compounds, used up to now, is the relatively high thermal conductivity λ at an order of magnitude of about 10 W/mK.

European document EP 1738381 A2, for example, describes a production method for a thermoelectric semiconductor alloy and a thermoelectric generator having a thermoelectric semiconductor alloy. The thermoelectric semiconductors include skutterudite, cobalt oxide, silicides and Heusler alloy.

According to the latest state of knowledge, there is no technology for semi-Heusler alloys for reducing thermal conductivity by intrinsic nanopatterning.

### SUMMARY OF THE INVENTION

An important aspect of the exemplary embodiments and/or exemplary methods of the present invention is, during the production of a semi-Heusler alloy, to add an additional element to the elements that are already contained in the semi-Heusler alloy, this element forming a second phase with a part of the elements of the semi-Heusler alloy, which is not miscible with the semi-Heusler alloy.

The exemplary embodiments and/or exemplary methods of the present invention permit the reduction in the thermal conductivity of semi-Heusler alloys while simultaneously maintaining the electrical conductivity and the thermoelectric voltage. In addition, it is an object of the exemplary embodiments and/or exemplary methods of the present invention to produce self-organizing microstructures and nanostructures in semi-Heusler alloys.

As an essential component, Heusler alloys have a Heusler phase. Heusler phases are intermetallic phases or even intermetallic compounds, having a special composition and lattice structure. They are ferromagnetic, although the elements contained therein do not have this property.

The semi-Heusler phases generally have the composition XYZ, where each letter stands for an alloying element, while the complete Heusler phases are composed according to the pattern X₂YZ. In this context, X and Y are transition elements, while Z is an element of the III-V main group. The alloying elements form order phases, so that the crystal structure is made up of four (in the XYZ type, one is unoccupied) cubic-face centered partial lattices that are nested within one another. The interactions between the atoms of the partial lattices have the effect of a nearly complete alignment (spin polarization) of the magnetic dipole moments, which expresses itself macroscopically as ferromagnetism.

By intermetallic compounds, compounds

1. between two or more real metals (T1 and T2),
2. between one or more real metals and one or more metals of the B subgroup,
3. between two or more metals of the B subgroup are understood, the properties at the transition from the 1^{st} to the 3^{rd} class becoming less metallic and increasingly more similar to chemical compounds.

An intermetallic semi-Heusler phase composed of three elements (X, Y, Z) per formula unit and 8 or 18 valence electrons is mostly a semiconductor or semi-metals. In this context, the elements may also be substituted by elements having the same number of valence electrons. The f electrons of the lanthanides and actinides do not count as valence electrons in this instance.

Because of the structural peculiarity of the semi-Heusler alloys, there are many possibilities of improving the thermoelectric properties.

One possibility of reducing the thermal conductivity of thermoelectric materials is to create structures in the material at which phonons, and therefore quasi particles, by which the heat is transported, are scattered, but electrons are not hindered in their flow. The thermal conductivity is reduced thereby, without the electrical conductivity becoming worse.

One method is doping the compound, by partially replacing an element by another element (having more or fewer valence electrons) from a bordering group of the periodic system. The electrical conductivity is able to be increased thereby. In addition, the doping makes possible the setting as an n- or p-conductor.

Because of these possibilities of variation, a very large number of compounds is also possible for a single semi-Heusler alloy.

One additional method is the partial substitution or multiple partial substitution with elements of the same group, in order to achieve an additional reduction in the thermal conductivity and an increase in the Seebeck coefficient by tailoring the electron system (bandgap engineering).

This approach assumes that the material is able to be synthesized in such a way that two immiscible phases are created, which are both thermodynamically stable. In this context, if there is success in producing structures which are in the range of <5 μm, which may be <1 μm, particularly being <100 nm, these structures are suitable for reducing the thermal conductivity. The separation is optimal if the structures produced are in the nm range, which may be <10 nm.

Using such materials, the efficiency of electric generators may be increased, for example, since these produce current with the aid of temperature differences. This is designated as the Seebeck effect. Using this, one could, for example, increasingly economically utilize unused waste heat in an automobile or from the hot gas waste heat of industrial thermal processes.

By the partial replacement of at least one element in the semi-Heusler structure, metallic inclusions occur in the semiconducting or semimetallic matrix. If there are metallic inclusions in this matrix, then as a result of the scattering of the phonons at the phase boundary of matrix-“metallic inclusions”, a significant reduction in the thermal conductivity may take place.

Accordingly, compounds according to the exemplary embodiments and/or exemplary methods of the present invention are those inorganic, intermetallic compounds which contain at least two elements per formula unit, which are made up of at least 2 phases, at least one being semiconducting or semimetallic.

In the main phase (at least 70% of the overall proportion of the compound) an intermetallic compound may be involved, having a cubic symmetry, and may have no structural distortion, but possibly a slight one. By structural deviation one should understand a distortion of the lattice parameters by more than 10% of the crystal structure of the elementary cell.

The cubic symmetry is determined, as a first approximation, by the radii ratios of the atoms. Ideally, the elements and the stoichiometry are selected in such a way that the resulting main phase is classed with the semi-Heusler phases and has 18 valence electrons.

It is furthermore expedient that the compounds according to the exemplary embodiments and/or exemplary methods of the present invention demonstrate a semiconducting behavior or a metal-semiconductor junction or a metal-semimetal junction.

The at least one subsidiary phase (less than 30% of the overall proportion of the compound, to avoid a metallic phase that may be less than 5% of the overall proportion of the compound) is metallic inclusions of disarranged structure. Parts of the at least one subsidiary phase are closed in together to form small regions, which, however, are not connected to one another, and therefore have no compound with one another.

The at least one subsidiary phase is created during the preparation process of the inorganic, intermetallic compound and does not have to be introduced retroactively.

At least one of the subsidiary phases created should be metallic.

The inorganic, intermetallic compound according to the present invention stands out by its low thermal conductivity of <4 W/mK at a simultaneously higher electrical conductivity of >1.8×10⁵ S/m. The inorganic, intermetallic compound has a Seebeck coefficient >±100 uV/Knowledge, a high resistance to thermal decomposition and a high chemical stability.

### Variants of the Embodiment

The assumption for a microstructuring is two semi-Heusler (XYZ) or two Heusler compounds (X₂YZ) or a Heusler and a semi-Heusler compound that are not miscible with each other. This is always the case among Heusler compounds of which the one has early transition metals or rare earth atoms on the octahedron gaps (Y places) and the other compound has a late transition element on the octahedron gaps (Y places).

The sample preparation may be made in various ways.

For one thing, powder or metal pieces of the elements used may be weighed in in a certain stoichiometric, element-dependent ratio the compounds may be weighed in separately.

The melting may take place in an electric arc furnace under a protective gas atmosphere. In the sample preparation, one should particularly make sure of an oxygen-free and anhydrous atmosphere. In order to obtain a homogeneous sample, the samples are turned over and also melted from the other side.

For a better homogenization, the samples may subsequently be submitted to an additional heat treatment. For this, the samples are melted into an evacuated quartz glass ampoule and kept in a tube oven (from Carbolite) between 700° C. and 1000° C. for one to four weeks. Thereafter the ampoules are quenched by pushing them directly from the tube oven into ice water, in order to fix the modification at the corresponding temperature.

It is also possible, however, to sinter the compound of the elements, molten in the quartz ampoules, under a protective gas atmosphere or a vacuum at temperatures of more than 400° C.

A further possibility for sample preparation is the preparation via ball milling.

In this context, the elements in the form of powder are weighed in in the corresponding stoichiometry and the powder mixture is placed into a milling cup with milling balls. The milling cup is closed airtight under a protective atmosphere, in order to avoid the oxidation of the sample during the preparation process, and is subsequently mounted into a planetary ball mill.

After ca. 10 hours of milling, the semi-Heusler compound is created, although the process has to be interrupted for ca. 20 minutes per hour in order to avoid overheating.

A further method of compressing the powder obtained by the ball milling is the process of spark plasma sintering. In this process, the sample is highly compressed in the heated state. Typical values for spark plasma sintering of semi-Heusler compounds, at a temperature between 1000K and 1300K are ca. 50 MPa for 5-20 minutes. The advantage of spark plasma sintering, compared to hot pressing, is in the low process temperature and the high sintering speed. Thereby, in contrast to hot pressing, grain growth is avoided to the greatest extent.

Other methods, such as preparing the powder from the elements by reaction under protective gas in a ball mill and subsequent melt spinning or melting the element mass in an induction oven, are also possible.

In the following, the exemplary embodiments and/or exemplary methods of the present invention are explained in greater detail with reference to examples and figures.

### BRIEF DESCRIPTION OF THE DRAWINGS

FIG. 1 shows an X-ray structure measurement, CoTiSb samples prepared by various methods, and a comparative measurement |:|:| mixture of the elements.

FIG. 2 shows grid pattern electron microscope images of a structure and an element distribution in CoTi_{0.5}Mn_{0.5}Sb.

FIG. 3 shows grid pattern electron microscope images of a structure and an element distribution in Co₂Ti₁₋ₓMnₓSn.

### DETAILED DESCRIPTION

The examples are as follows:

### Example 1

Preparation of a microstructured material from two semi-Heusler compounds (CoTiSb:CoMnSb in a ratio of 1:1)

The compound CoTiSb is not miscible with CoMnSb, since a mixture gap exists between the two compounds.

CoTiSb is a semiconductor, CoMnSb is a semimetallic ferromagnet.

Powder or metal pieces of the four elements Co:Ti:Mn:Sb are weighed in the stoichiometric ratios 2:1:1:2 or even the two compounds Co:Ti:Sb and Co:Mn:Sb are weighed in separately in the ratio 1:1:1. Then there takes place the melting in the electric arc furnace under a protective gas atmosphere.

In the sample preparation by ball milling, the elements are weighed in powder form in the stoichiometric ratio of 2:1:1:2 and the powder mixture is placed in a milling cup made of zirconium oxide having milling balls made of zirconium oxide. The milling cup is closed in an airtight manner under argon, mounted into a planetary ball mill (of the firm Retsch, PM100) and milled for ca. 10 hours, using an interruption of ca. 20 minutes per hour.

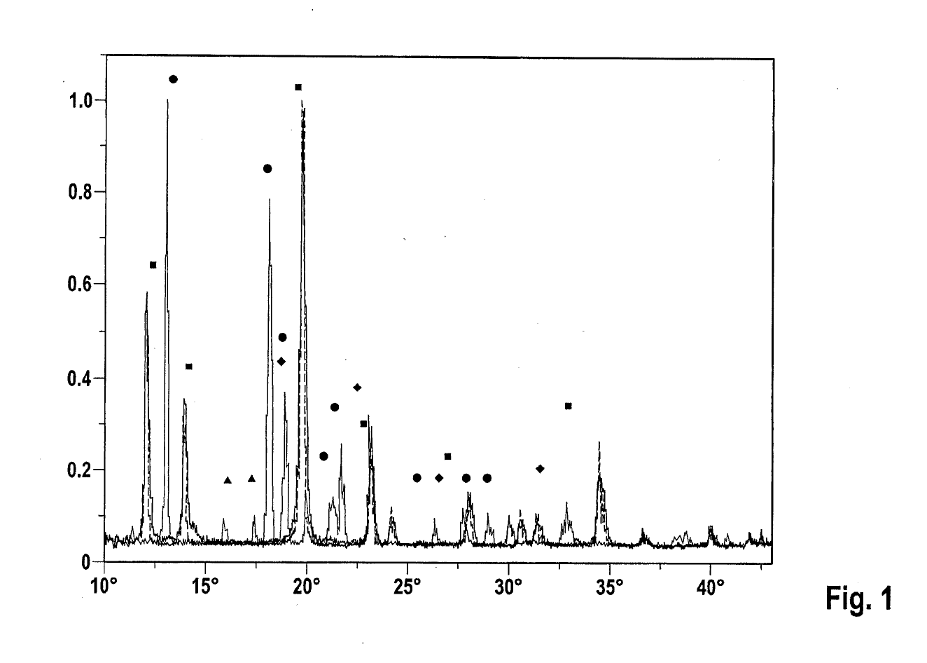

FIG. 1 shows an X-ray structural measurement of CoTiSb samples prepared by different methods, the sample prepared by arcmelting and a sample prepared for 13 hours by ball milling. In comparison to this there is the measurement of an |:|:| mixture of the elements.

One may clearly see that, after 13 hours of milling, the elements are no longer present, but have been completely converted to the semi-Heusler compound, and that the same structure is created as by the arcmelting process.

In order subsequently to measure on the samples magnetic and thermoelectrical properties, as well as the transport properties, the freshly prepared powder is compressed to form a disk or a rod, with the aid of a hydraulic press at ca. 60 kN.

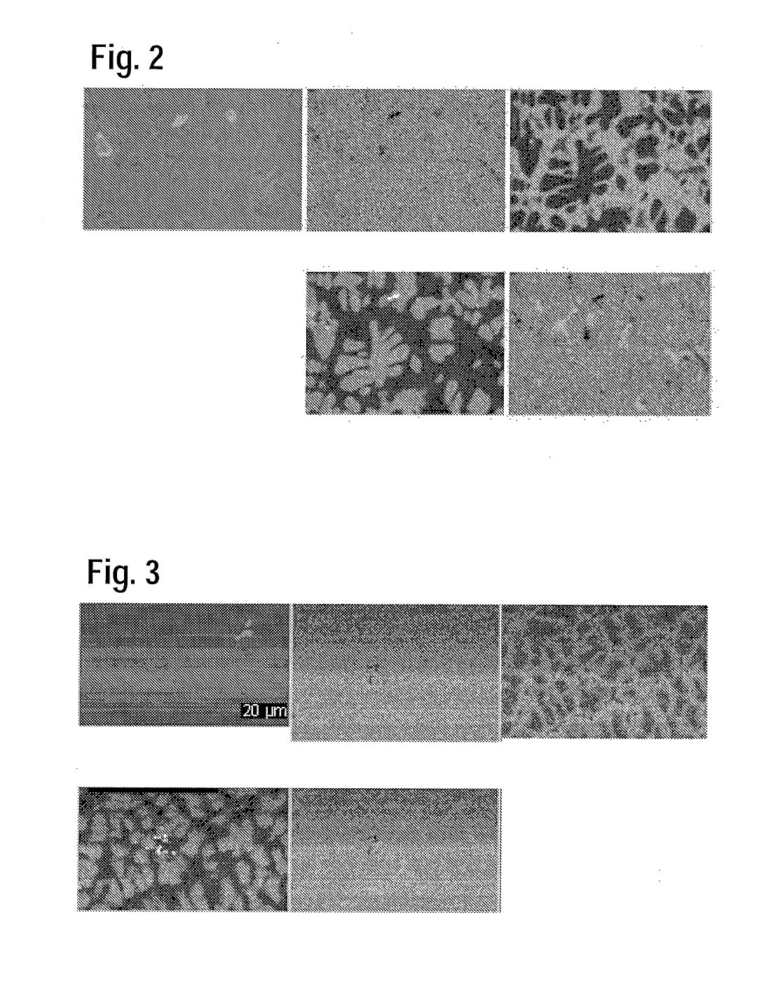

In addition, the samples are investigated for the correct structure by X-ray photography, and are subsequently investigated for separation behavior (see FIG. 2) in a scanning electron microscope (SEM) in combination with EDX (energy-dispersive X-ray spectroscopy).

### Example 2

Preparation of a microstructured material made of two Heusler compounds (Co₂TiSn:Co₂MnSn in a ratio of 1:1).

The compound Co₂TiSn is not miscible with Co₂MnSn, since there exists a mixture gap between the two compounds.

The sample preparation may take place in various ways. For one, powder or metal pieces of the four elements Co:Ti:Mn:Sn may be weighed in in the stoichiometric ratios 4:1:1:2, or the two compounds Co:Ti:Sn and Co:Mn:Sn may be weighed in separately in a ratio 2:1:1.

The melting may take place in an electric arc furnace under a protective gas atmosphere.

After that, the weight is checked. In this context, samples demonstrating a loss of mass of more than 1% are discarded.

The samples are investigated for correct structure using X-ray photography and are subsequently investigated for disintegration behavior (see FIG. 3) in a scanning electron microscope (SEM) in combination with EDX (energy-dispersive X-ray spectroscopy. The size of the eliminations is able to be controlled by the cooling process.

1-16. (canceled)

17. An inorganic, intermetallic compound, comprising:
a compound having at least two elements per formula unit and which is made up of at least two phases, wherein at least one phase is semiconducting or semimetallic.

18. The inorganic, intermetallic compound of claim 17, wherein the at least two phases are not miscible with each other.

19. The inorganic, intermetallic compound of claim 18, wherein the at least two phases are thermodynamically stable.

20. The inorganic, intermetallic compound of claim 19, wherein, because of the separation of the at least two phases, disarranged structures <1 μm are developed.

21. The inorganic, intermetallic compound of claim 17, wherein the inorganic, intermetallic compound has a main phase which includes at least 70% of the overall proportion of the inorganic, intermetallic compound.

22. The inorganic, intermetallic compound of claim 20, wherein the main phase is an intermetallic compound.

23. The inorganic, intermetallic compound of claim 20, wherein the main phase has a cubic symmetry having preferably no structural deviation, possibly a slight structural deviation, structural deviation being understood to mean a distortion of the grid parameters by less than 10%.

24. The inorganic, intermetallic compound of claim 20, wherein the main phase is a member of the semi-Heusler phases.

25. The inorganic, intermetallic compound of claim 20, wherein the main phase has 18 valence electrons.

26. The inorganic, intermetallic compound of claim 20, wherein the main phase has a semiconducting behavior.

27. The inorganic, intermetallic compound of claim 20, wherein the main phase has a metal-semiconductor junction or a metal-semimetal junction.

28. The inorganic, intermetallic compound of claim 20, wherein the main phase has a semimetallic behavior.

29. The inorganic, intermetallic compound of claim 17, wherein the inorganic, intermetallic compound has a subsidiary phase which includes less than 30% of the overall proportion of the inorganic, intermetallic compound.

30. The inorganic, intermetallic compound of claim 28, wherein the subsidiary phase includes metallic inclusions having a disarranged structure.

31. The inorganic, intermetallic compound of claim 29, wherein the subsidiary phase is created during the preparation process.

32. The inorganic, intermetallic compound of claim 17, wherein the inorganic, intermetallic compound is the main component of an alloy.

33. The inorganic, intermetallic compound of claim 19, wherein, because of the separation of the at least two phases, disarranged structures 100 nm are developed.

34. The inorganic, intermetallic compound of claim 19, wherein, because of the separation of the at least two phases, disarranged structures <30 nm are developed.
